(19) United States
(12) Patent Application Publication
(10) Pub. No.: US 2024/0324202 A1
(43) Pub. Date: Sep. 26, 2024

(54) MEMORY DEVICE AND MANUFACTURING METHOD OF THE MEMORY DEVICE

(71) Applicant: SK hynix Inc., Icheon-si (KR)

(72) Inventor: Jae Ho KIM, Icheon-si (KR)

(73) Assignee: SK hynix Inc., Icheon-si (KR)

(21) Appl. No.: 18/454,621

(22) Filed: Aug. 23, 2023

(30) Foreign Application Priority Data
Mar. 20, 2023 (KR) 10-2023-0035901

(51) Int. Cl. H10B 43/27; H01L 23/00; H10B 43/35

(52) U.S. Cl. CPC H10B 43/27; H01L 23/562; H10B 43/35

(57) ABSTRACT

Provided is a memory device and a manufacturing method of the memory device. The memory device includes: a source line; a dummy stack structure located on the source line; a main stack structure located on the dummy stack structure; and a source contact in contact with the source line while penetrating the main stack structure and the dummy stack structure. The dummy stack structure includes: a first material layer located on the source line; and second material layers, blocking insulating layers, and dummy conductive layers, located on the first material layer. The main stack structure includes insulating layers and gate conductive layers, which are alternately stacked on the dummy stack structure.

### CROSS-REFERENCE TO RELATED APPLICATION

The present application claims priority under 35 U.S.C. § 119(a) to Korean patent application number 10-2023-0035901 filed on Mar. 20, 2023, in the Korean Intellectual Property Office, the entire disclosure of which is incorporated by reference herein.

### BACKGROUND

### 1. Technical Field

The present disclosure generally relates to a memory device and a manufacturing method of the memory device, and more particularly, to a memory device including a source contact and a support structure and a manufacturing method of the memory device.

### 2. Related Art

A memory device may include a memory cell array in which data is stored, a peripheral circuit configured to perform a program, read or erase operation, and a control circuit configured to control the peripheral circuit.

The memory cell array may include a plurality of memory blocks. When the memory blocks are formed in a three-dimensional structure, the memory blocks may be separated from each other by slit regions.

The memory blocks formed in the three-dimensional structure may include a stack structure in which memory cell are stacked in a vertical direction from a substrate. The stack structure may include a plurality of gate lines and a plurality of insulating layers, which are alternately stacked. When the memory blocks are configured with the stack structure, support structures may be used to prevent the stack structure from being bent or destroyed in a manufacturing process of the memory device. The support structures may be located at both ends of the stack structure or be located between the memory blocks.

Since the size of structures included in the memory cell array and the distance between the structures decrease as the degree of integration of the memory device, a bridge may occur between some components in the manufacturing process of the memory device. The bridge occurring between the components which are to be electrically blocked from each other is a defect, and therefore, the yield of the manufacturing process of the memory device may be deteriorated.

### SUMMARY

In accordance with an aspect of the present disclosure, there is provided a memory device. In an embodiment, the memory device may include: a source line; a dummy stack structure located on the source line; a main stack structure located on the dummy stack structure; and a source contact in contact with the source line while penetrating the main stack structure and the dummy stack structure, wherein the dummy stack structure includes: a first material layer located on the source line; and second material layers, blocking insulating layers, and dummy conductive layers, located on the first material layer, and wherein the main stack structure includes insulating layers and gate conductive layers, which are alternately stacked on the dummy stack structure.

In accordance with another aspect of the present disclosure, there is provided a memory device. In an embodiment, the memory device may include: a source pad included in a source line; blocking insulating layers located on the source pad; material layers located at both ends of the blocking insulating layers; a source select line, a word line, and a drain select line, located on the blocking insulating layers and the material layers; and a source contact in contact with the source pad while penetrating the drain select line, the word line, and the source select line. The source contact penetrates the blocking insulating layers to space apart the blocking insulating layers from each other.

In accordance with still another aspect of the present disclosure, there is provided a method of manufacturing a memory device. In an embodiment, the method may include: stacking a first material layer and a second material layer on a source layer including an etch stop layer; forming first and second isolation trenches spaced apart from each other in the second material layer on the etch stop layer; forming first and second blocking insulating layers in the first and second isolation trenches; alternately stacking third material layers and fourth material layers on the first and second blocking insulating layers and the second material layer, thereby forming a pre-stack structure including the first to fourth material layers and the first and second blocking insulating layers; forming a support structure in contact with the source layer while penetrating the pre-stack structure; forming a slit trench penetrating the pre-stack structure between the first and second blocking insulating layers; removing the second and fourth material layers exposed through the slit trench; filling a first conductive layer in regions in which the second and fourth material layers are removed; removing the etch stop layer exposed through the slit trench; and filling a second conductive layer for a source pad in a region in which the etch stop layer is removed.

### BRIEF DESCRIPTION OF THE DRAWINGS

Examples of embodiments will now be described more fully hereinafter with reference to the accompanying drawings; however, they may be embodied in different forms and should not be construed as limited to the embodiments set forth herein.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a diagram illustrating a memory device.

FIG. 2 is a diagram illustrating a memory cell array.

FIG. 3 is a sectional view illustrating a memory block in accordance with a first embodiment of the present disclosure.

FIG. 4 is a perspective view illustrating the memory block in accordance with the first embodiment of the present disclosure.

FIGS. 5A, 5B, 5C, 5D, 5E, 5F, 5G, 5H, 5I, 5J, 5K, 5L, 5M, 5N, 5O, 5P, 5Q, and 5R are views illustrating a manufacturing method of the memory device in accordance with the first embodiment of the present disclosure.

FIG. 6 is a sectional view illustrating a memory block in accordance with a second embodiment of the present disclosure.

FIG. 7 is a perspective view illustrating the memory block in accordance with the second embodiment of the present disclosure.

FIG. 8 is a sectional view illustrating a memory block in accordance with a third embodiment of the present disclosure.

FIG. 9 is a diagram illustrating a memory card system to which the memory device of the present disclosure is applied.

FIG. 10 is a diagram illustrating a Solid State Drive (SSD) system to which the memory device of the present disclosure is applied.

### DETAILED DESCRIPTION

The specific structural and functional descriptions disclosed herein are merely illustrative for the purpose of describing embodiments according to the concept of the present disclosure. Additional embodiments according to the concept of the present disclosure can be implemented in various forms. Thus, the present disclosure should not be construed as limited to the embodiments set forth herein.

Hereinafter, it will be understood that, although the terms “first,” “second,” etc. may be used herein to describe various elements, these elements should not be limited by these terms. These terms are only used to distinguish one element from another element. It will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present.

Various embodiments provide a memory device and a manufacturing method of the memory device, which can reduce a defect of the memory device.

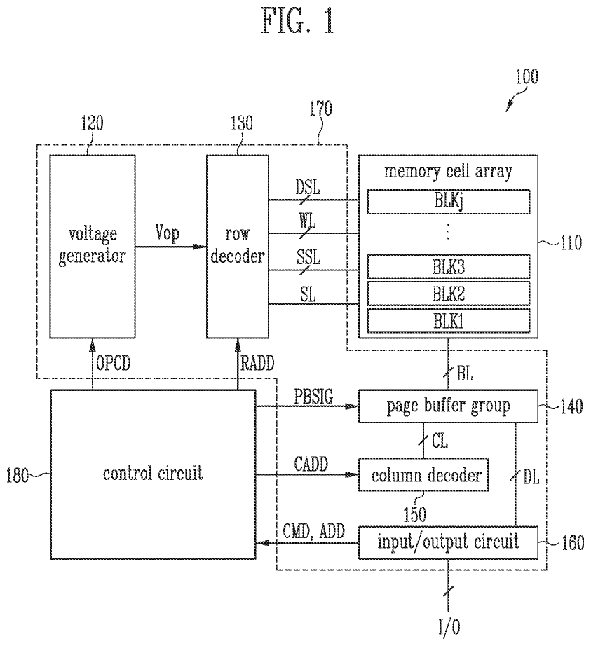

FIG. 1 is a diagram illustrating a memory device.

Referring to FIG. 1, the memory device 100 may include a memory cell array 110, a peripheral circuit 170, and a control circuit 180.

The memory cell array 110 may include first to jth memory blocks BLK1 to BLKj. Each of the first to jth memory blocks BLK1 to BLKj may include memory cells capable of storing data. Drain select lines DSL, word lines WL, source select lines SSL, and a source line may be connected to each of the first to jth memory blocks BLK1 to BLKj, and bit lines BL may be commonly connected to the first to jth memory blocks BLK1 to BLKj. The first to jth memory blocks BLK1 to BLKj may be formed in a two-dimensional structure or a three-dimensional structure. Memory blocks having the two-dimensional structure may include memory cells arranged in parallel to a substrate. Memory blocks having the three-dimensional structure may include memory cells stacked in a vertical direction from a substrate. In this embodiment, memory blocks formed in a three-dimensional structure are disclosed.

The memory cells may store one-bit or two-or-more-bit data according to a program manner. For example, a manner in which one-bit data is stored in one memory cell is referred to as a single level cell (SLC) manner, and a manner in which two-bit data is stored in one memory cells is referred to as a multi-level cell (MLC) manner. A manner in which three-bit data is stored in one memory cell is referred to as a triple level cell (TLC) manner, and a manner in which four-bit data is stored in one memory cell is referred to as a quad level cell (QLC) manner. In addition, five-or-more-bit data may be stored in one memory cell.

The peripheral circuit 170 may be configured to perform a program operation for storing data, a read operation for outputting data stored in the memory cell array 110, and an erase operation for erasing data stored in the memory cell array 110. For example, the peripheral circuit 170 may include a voltage generator 120, a row decoder 130, a page buffer group 140, a column decoder 150, and an input/output circuit 160.

The voltage generator 120 may generate various operating voltages Vop used for a program operation, a read operation, or an erase operation in response to an operation code OPCD. For example, the voltage generator 120 is configured to generate program voltages, turn-on voltages, turn-off voltages, negative voltages, precharge voltages, verify voltages, read voltages, pass voltages, and erase voltages in response to the operation code OPCD. The operating voltages Vop generated by the voltage generator 120 may be applied to drain select lines DSL, word lines WL, source select lines SSL, and a source line SL of a selected memory block through the row decoder 130.

The program voltages are voltages applied to a selected word line among word lines WL in a program operation, and may be used to increase a threshold voltage of memory cells connected to the selected word line. The turn-on voltages may be applied to the drain select lines DSL or the source select lines SSL, and be used to turn on drain select transistors or source select transistors. The turn-off voltages may be applied to the drain select lines DSL or the source select lines SSL, and be used to turn off the drain select transistors or the source select transistors. For example, the turn-off voltage may be set to 0V. The precharge voltages are voltages higher than 0V, and may be applied to the bit lines in a read operation. The verify voltages may be used in a verify operation for determining whether a threshold voltage of selected memory cells has been increased to a target level. The verify voltages may be set to various levels according to the target level, and be applied to a selected word line.

The read voltages may be applied to a selected word line in a read operation of selected memory cells. For example, the read voltages may be set to various levels according to a program manner of the selected memory cells. The pass voltages are voltages applied to unselected word lines among the word lines WL in a program or read operation, and may be used to turn on memory cells connected to the unselected word lines.

The erase voltages may be used in an erase operation for erasing memory cells included in a selected memory block, and be applied to the source line SL.

The row decoder 130 may be configured to transmit the operating voltages Vop to drain select lines DSL, word lines WL, source select lines SSL, and a source line SL, which are connected to a selected memory block, according to a row address RADD. For example, the row decoder 130 may be connected to the voltage generator 120 through global lines, and may be connected to the first to jth memory blocks BLK1 to BLKj through the drain select lines DSL, the word lines WL, the source select lines SSL, and the source line SL.

The page buffer group 140 may include page buffers (not shown) connected to each of the first to jth memory blocks BLK1 to BLKj. The page buffers (not shown) may be connected to the first to jth memory blocks BLK1 to BLKj respectively through the bit lines BL. In a read operation, the page buffers (not shown) may sense a current or a voltage of the bit lines BL, which varies according to threshold voltages of selected memory cells, and store sensed data, in response to page buffer control signals PBSIG.

The column decoder 150 may be configured to transmit data between the page buffer group 140 and the input/output circuit 160 in response to a column address CADD. For example, the column decoder 150 may be connected to the page buffer group 140 through column lines CL, and transmit enable signals through the column lines. The page buffers (not shown) included in the page buffer group 140 may receive or output data through data lines DL in response to the enable signals.

The input/output circuit 160 may be configured to receive or output a command CMD, an address ADD, or data through input/output lines I/O. For example, the input/output circuit 160 may transmit, to the control circuit 180, a command CMD and an address ADD, which are received from an external controller, through the input/output lines I/O, and transmit data received from the external controller to the page buffer group 140 through the input/output lines I/O. Alternatively, the input/output circuit 160 may output data transferred from the page buffer group 140 to the external controller through the input/output lines I/O.

The control circuit 180 may output an operation code OPCD, the row address RADD, the page buffer control signals PBSIG, and the column address CADD in response to the command CMD and the address ADD. For example, when the command CMD input to the control circuit 180 is a command corresponding to a program operation, the control circuit 180 may control the peripheral circuit 170 to perform a program operation of a memory block selected by the address ADD. When the command CMD input to the control circuit 180 is a command corresponding to a read operation, the control circuit 180 may control the peripheral circuit 170 to perform the read operation of the selected memory block and output read data. When the command CMD input to the control circuit 180 is a command corresponding to an erase operation, the control circuit 180 may control the peripheral circuit 170 to perform the erase operation of the selected memory block.

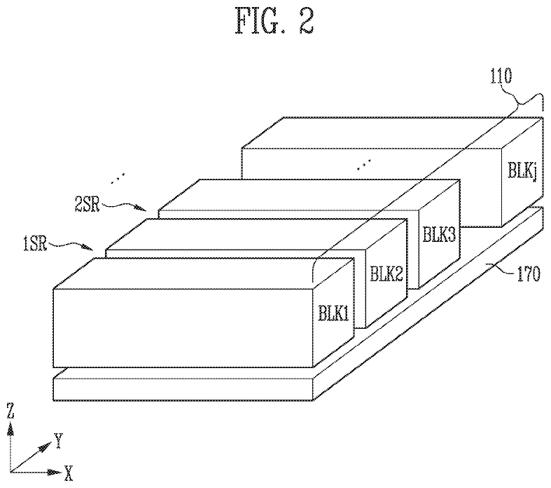

FIG. 2 is a diagram illustrating a memory cell array.

Referring to FIG. 2, the memory cell array 110 may be located on the peripheral circuit 170, but the positions of the memory cell array 110 and the peripheral circuit 170 are not limited to those shown in FIG. 2. For example, the memory cell array 110 may be located on the same plane as the peripheral circuit 170, and the memory cell array 110 and the peripheral circuit 170 may be in contact with each other after the memory cell array 110 and the peripheral circuit 170 are formed on different substrates.

The memory cell array 110 may include first to jth memory blocks BLK1 to BLKj. The first to jth memory blocks BLK1 to BLKj may be disposed to be spaced apart from each other along a Y direction. The first to jth memory blocks BLK1 to BLKj may be configured identically to one another, and be separated from each other by slit regions 1SR, 2SR, . . . . Each of the slit regions 1SR, 2SR, . . . may extend along an X direction. For example, the first and second memory blocks BLK1 and BLK2 may be separated from each other by a first slit region 1SR, and the second and third memory blocks BLK2 and BLK3 may be separated from each other by a second slit region 2SR.

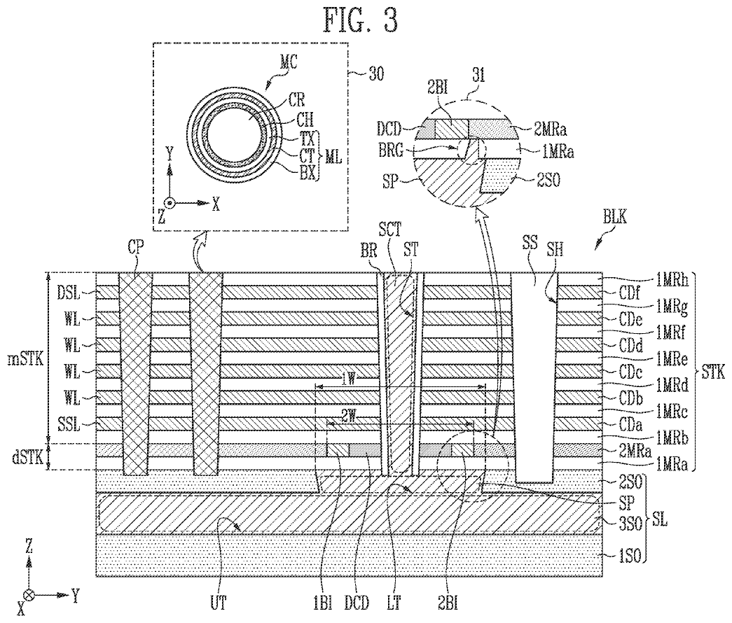

FIG. 3 is a sectional view illustrating a memory block in accordance with a first embodiment of the present disclosure.

Referring to FIG. 3, the memory block BLK may be any one of the first to jth memory blocks BLK1 to BLKj shown in FIG. 2. The memory block BLK may be located above a lower structure (not shown). For example, the lower structure (not shown) may be a substrate or a portion of a peripheral circuit.

The memory block BLK may include a source line SL, a stack structure STK, cell plugs CP, a source contact SCT, a support structure SS, and first and second blocking insulating layers 1BI and 2BI.

The source line SL may include first to third source layers 1SO to 3SO and a source pad SP. The first to third source layers 1SO to 3SO and the source pad SP may be formed of a conductive material such as poly-silicon, tungsten or nickel. The third conductive layer 3SO and the source pad SP may be formed of the same material, and the first to third source layers 1SO to 3SO may be formed of the same material or different materials. The third source layer 3SO may be formed on the first source layer 1SO. The second source layer 2SO and the source pad SP may be formed on the third source layer 3SO, and the source pad SP may be formed in the second source layer 2SO.

The stack structure STK may include a dummy stack structure dSTK and a main stack structure mSTK. The dummy stack structure dSTK may be located on the source line SL, and the main stack structure mSTK may be located on the dummy stack structure dSTK.

The dummy stack structure dSTK may include a first material layer 1MRa, second material layers 2MRa, the first and second blocking insulating layers 1BI and 2BI, and dummy conductive layers DCD. The first material layer 1MRa may be located on the source line SL, and the second material layers 2MRa, the first blocking insulating layer 1BI, the second blocking insulating layer 2BI, and the dummy conductive layers DCD may be located on the first material layer 1MRa. The first and second blocking insulating layers 1BI and 2BI may be located at both ends of the dummy conductive layers DCD, and the second material layers 2MRa may be located at both ends of the first and second blocking insulating layers 1BI and 2BI. The first material layer 1MRa may be formed of an oxide layer. In an embodiment, the main stack structure may include the first material layers 1MRb to 1MRh, the first material layers 1MRb to 1MRh may be insulating layers, and the insulating layers may be alternately stacked with gate conductive layers CDa to CDf on the dummy stack structure dSTK. The second material layers 2MRa may be formed of a nitride layer. The first and second blocking insulating layers 1BI and 2BI may be formed of an oxide layer. The dummy conductive layers DCD may be formed of a metal material such as tungsten (W), molybdenum (Mo), cobalt (Co) or nickel (Ni), or a semiconductor material such as silicon (Si) or poly-silicon (Poly-Si), but the present disclosure is not limited thereto.

The main stack structure mSTK may include first material layers 1MRb to 1MRh and gate conductive layers CDa to CDf, which are alternately stacked. The first material layers 1MRb to 1MRh may be formed of an oxide layer. The gate conductive layers CDa to CDf may be formed of a metal material such as tungsten (W), molybdenum (Mo), cobalt (Co) or nickel (Ni), or a semiconductor material such as silicon (Si) or poly-silicon (Poly-Si), but the present disclosure is not limited thereto. Each of the gate conductive layers CDa to CDf may be used as a source select line SSL, a word line WL, or a drain select line DSL according to a position thereof. For example, among the gate conductive layers CDa to CDf, a gate conductive layer CDa located at a lower portion may be used as the source select line SSL, a gate conductive layer CDf located at a upper portion may be used as the drain select line DSL, and gate conductive layers CDb to CDe located between the source select line SSL and the drain select line DSL may be used as word lines WL. FIG. 3 is a view schematically illustrating a structure of the memory block BLK, and therefore, the number of each of the source select line SSL, the word line WL, and the drain select line DSL is not limited to that shown in FIG. 3.

The cell plugs CP memory cells MC, and be in contact with the source line SL while vertically penetrating the stack structure STK. For example, the cell plugs CP may be in contact with the second source layer 2SO. A structure of the memory cells MC included in the cell plugs CP will be described as follows with reference to a plan view 30.

The memory cell MC may include a core pillar CR, a channel layer CH, a tunnel insulating layer TX, a charge trap layer CT, and a blocking layer BX. In an embodiment, a memory layer ML may include the tunnel insulating layer TX, the charge trap layer CT, and the blocking layer BX. The core pillar CR may have a circular pillar shape, and be formed of an insulating material or a conductive material. The channel layer CH may have a cylindrical shape surrounding a side surface of the core pillar CR, and be formed of poly-silicon. The tunnel insulating layer TX may have a cylindrical shape surrounding a side surface of the channel layer CH, and be formed of an oxide layer. The charge trap layer CT may have a cylindrical shape surrounding a side surface of the tunnel insulating layer TX, and be formed of a nitride layer. The blocking layer BX may have a cylindrical shape surrounding a side surface of the charge trap layer CT, and be formed of an oxide layer.

The source contact SCT may vertical penetrate the stack structure STK, and be in contact with the source pad SP. A barrier layer BR may be formed between the source contact SCT and the stack structure STK. The barrier layer BR may be formed of an insulating material. The source contact SCT may be formed of a conductive material, and be formed of the same material as the source pad SP. A conductive material may be simultaneously formed in a lower trench UT between the third and second source layers 3SO and 2SO, a landing trench LT in the second source layer 2SO, and a slit trench ST in the stack structure STK. Therefore, the third source layer 3SO formed in the lower trench UT, the source pad SP formed in the landing trench, and the source contact SCT formed in the slit trench ST may be formed of the same material. The words “simultaneous” and “simultaneously” as used herein with respect to processes mean that the processes take place on overlapping intervals of time. For example, if a first process takes place over a first interval of time and a second process takes place simultaneously over a second interval of time, then the first and second intervals at least partially overlap each other such that there exists a time at which the first and second processes are both taking place.

The support structure SS may penetrate the stack structure STK. For example, the support structure SS may be formed in a support hole SH penetrating the stack structure STK. The support structure SS may be in contact with the second source layer 2SO while penetrating the stack structure STK. The support structure SS may be formed of an insulating material. In an embodiment, the support structure SS may be formed to support the stack structure STK such that the stack structure STK is not destroyed or bent in a manufacturing process of the memory block BLK.

The first and second blocking insulating layers 1BI and 2BI may be located in the same layer as the second material layers 2MRa and the dummy conductive layer DCD. For example, the first and second blocking insulating layers 1BI and 2BI may be located in the second material layers 2MRa, and the second material layers 2MRa are not located between the first and second blocking insulating layers 1BI and 2BI. The dummy conductive layers DCD and the source contact SCT may be located between the first and second blocking insulating layers 1BI and 2BI, and the source contact SCT may penetrate between the dummy conductive layers DCD in a vertical direction. The first and second blocking insulating layers 1BI and 2BI may be formed of an oxide layer. When assuming that the width of a top surface of the source pad SP is a first width 1W, the width between both ends of the first and second blocking insulating layers 1BI and 2BI may have a second width 2W narrower than the first width 1W. For example, with respect to a section shown in FIG. 3, the width between a left side surface of the first blocking insulating layer 1BI and a right side surface of the second blocking insulating layer 2BI may be the second width 2W narrower than the first width 1W. In an embodiment, a top surface of the second source layer 2SO faces the first material layer 1MRa and extends in a horizontal direction along the X and Y directions. In an embodiment, a top surface of the source pad SP faces the first material layer 1MRa and extends in a horizontal direction along the X and Y directions.

In an embodiment, when a bridge BRG occurs from the source line SL in a process of forming the support structure SS (31), the bridge BRG may protrude upwardly to be in contact with the second material layers 2MRa, but occurrence of an electrical defect due to the bridge BRG can be prevented or mitigated by the second material layers 2MRa formed of an insulating material.

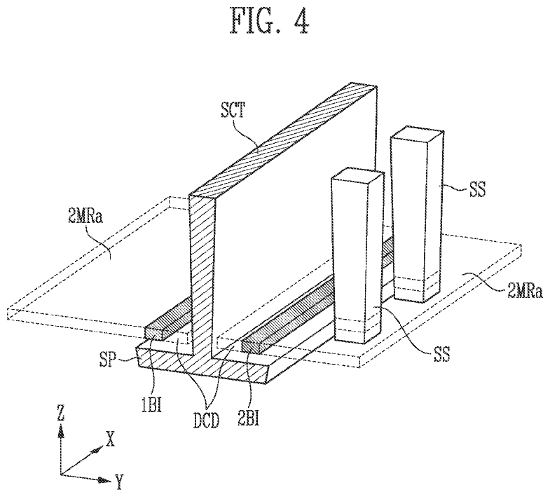

FIG. 4 is a perspective view illustrating the memory block in accordance with the first embodiment of the present disclosure.

Referring to FIGS. 3 and 4, the source contact SCT may be in contact with the source pad SP in a vertical direction (Z), and penetrate the dummy conductive layer DCD in the vertical direction. The dummy conductive layer DCD may be disposed to be spaced apart from the source contact SCT, and extend in the X direction. The first and second blocking insulating layers 1BI and 2BI may be respectively located at both ends of the dummy conductive layer DCD. The first and second blocking insulating layers 1BI and 2BI may be formed in a line shape extending in the X direction, and isolate the dummy conductive layer DCD and the second material layers 2MRa from each other. The second material layers 2MRa may be respectively located at both ends of the first and second blocking insulating layers 1BI and 2BI.

The second material layers 2MRa made of an insulating material instead of the source select line SSL are located above the source pad SP included in the source line SL. Thus, in an embodiment, although the bridge BRG protruding in the Z direction from the source line SL occurs, occurrence of a defect in which the source line SL and the source select line SSL are in contact with each other can be prevented or mitigated.

In the first embodiment, in order to allow the bridge BRG protruding from the source line SL not to be in contact with the source select line SSL, a manufacturing method of the memory device including the first and second blocking insulating layers 1BI and 2BI and a structure of the memory device are disclosed.

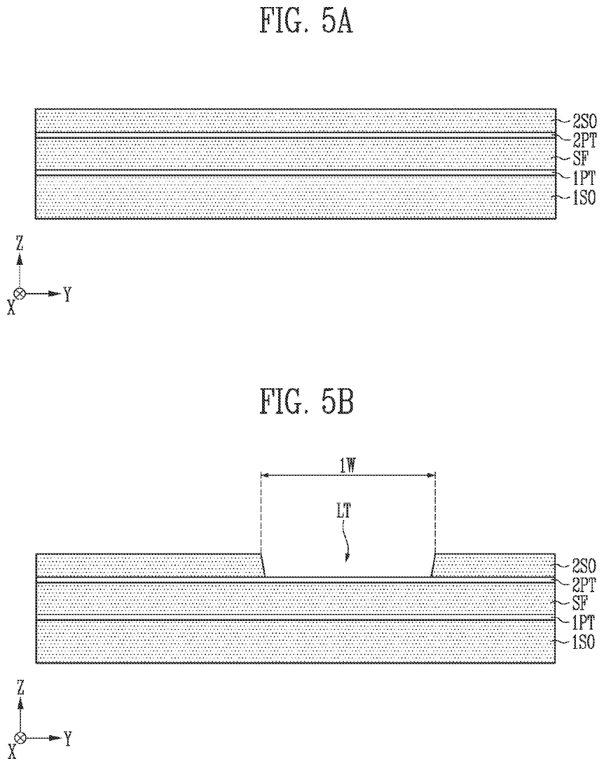

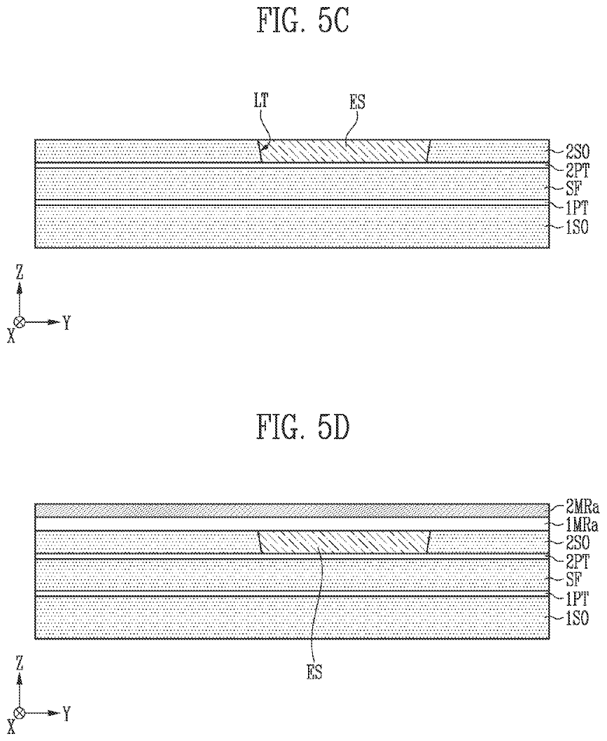

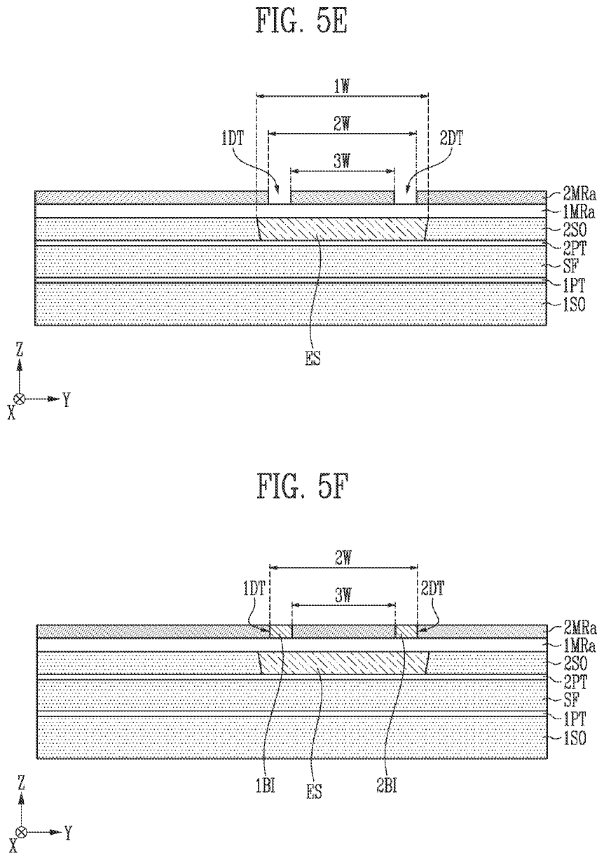

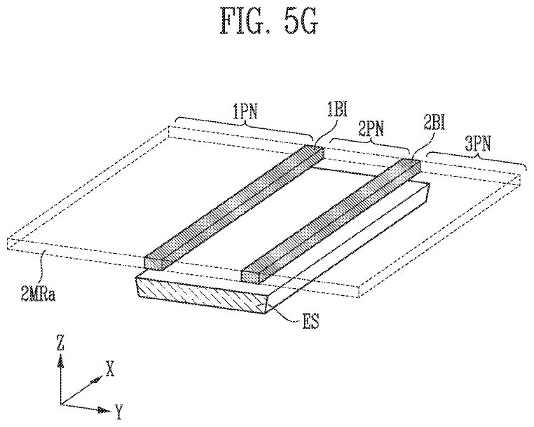

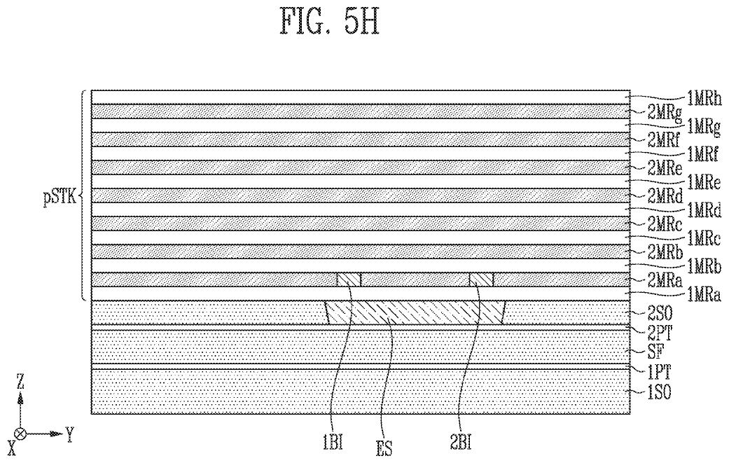

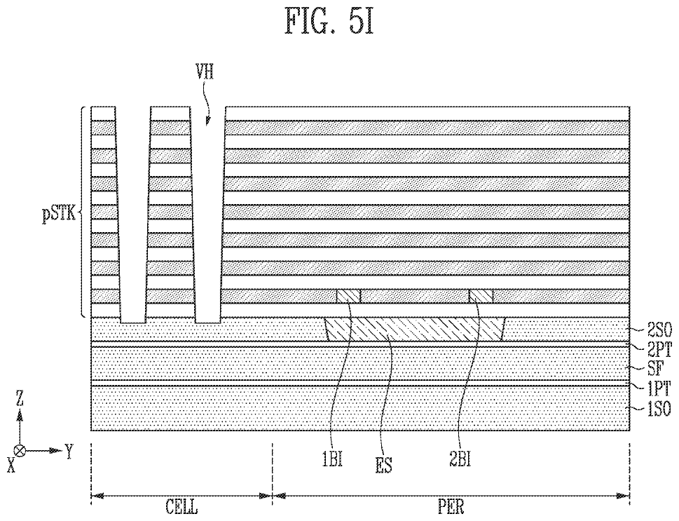

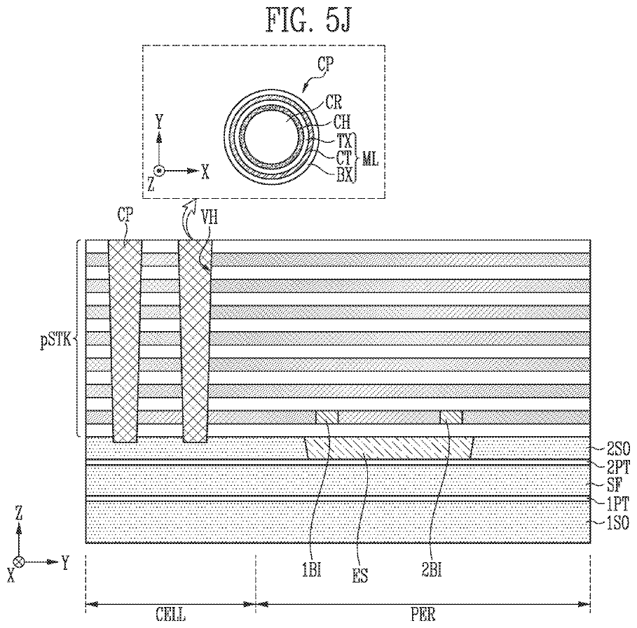

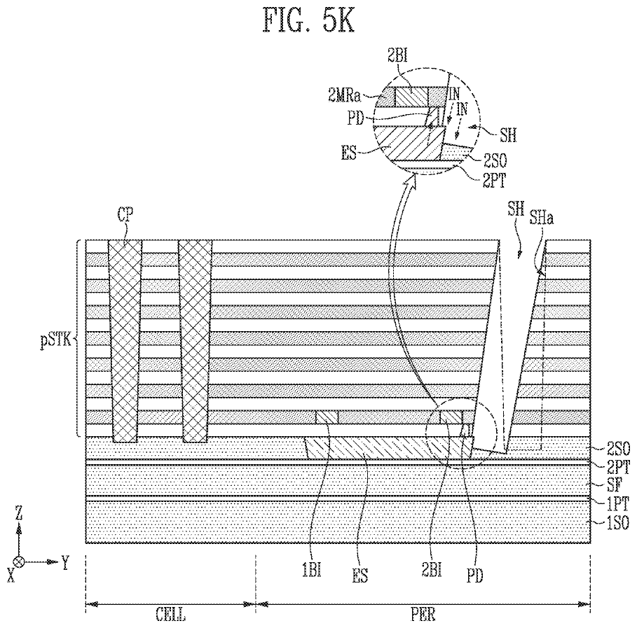

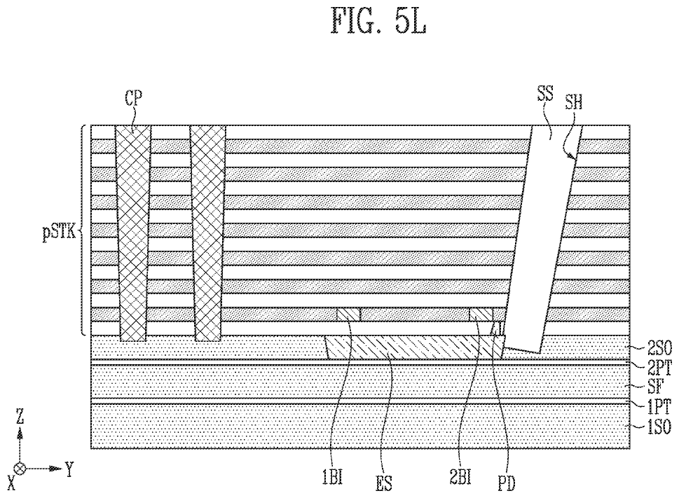

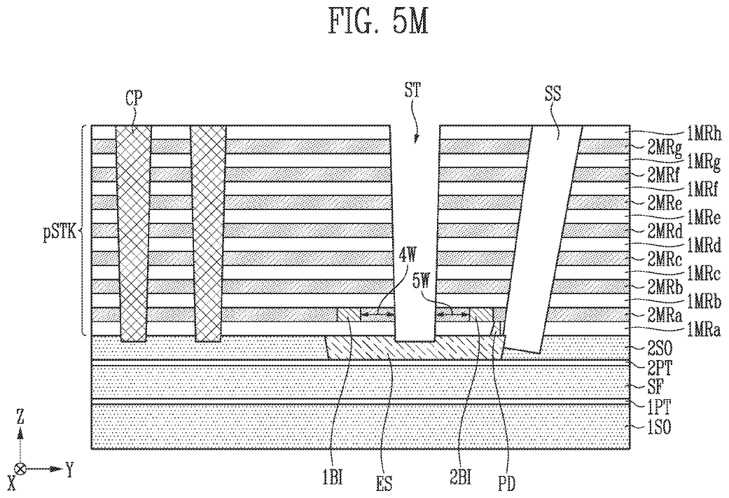

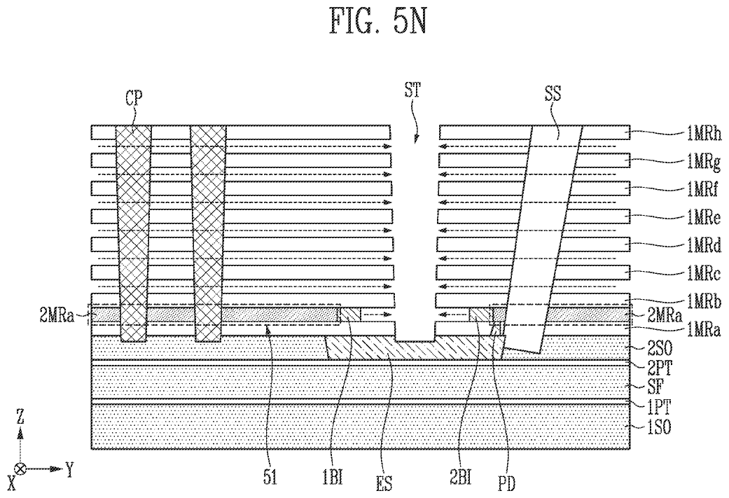

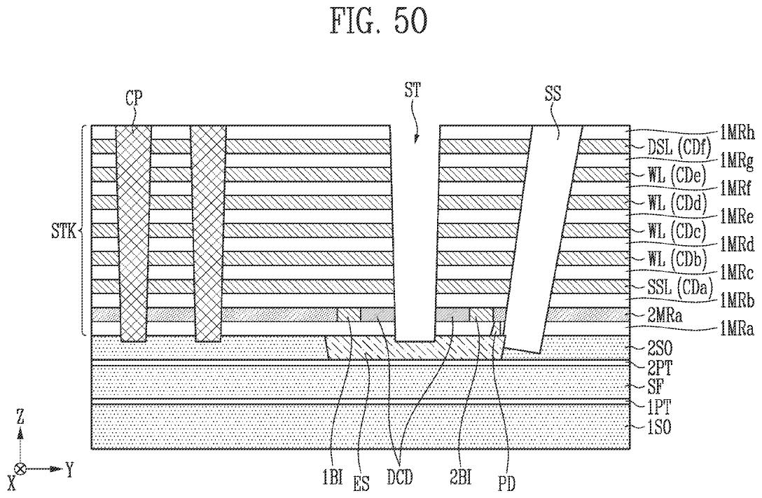

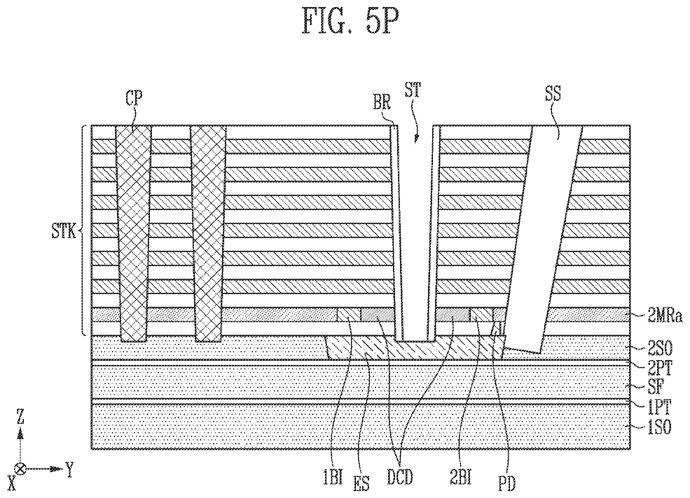

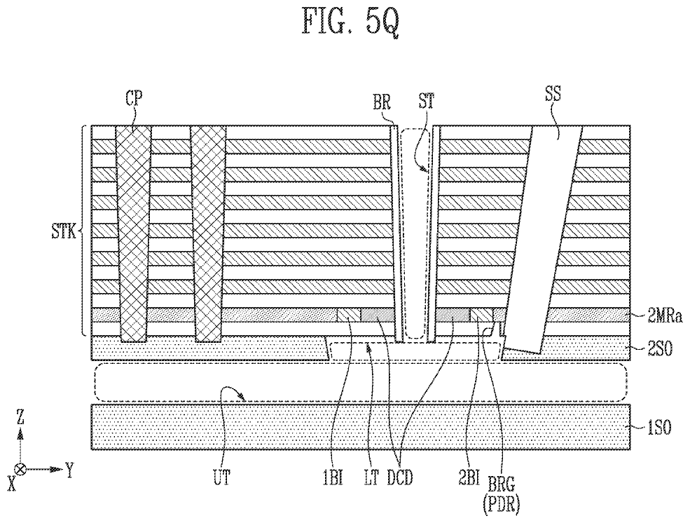

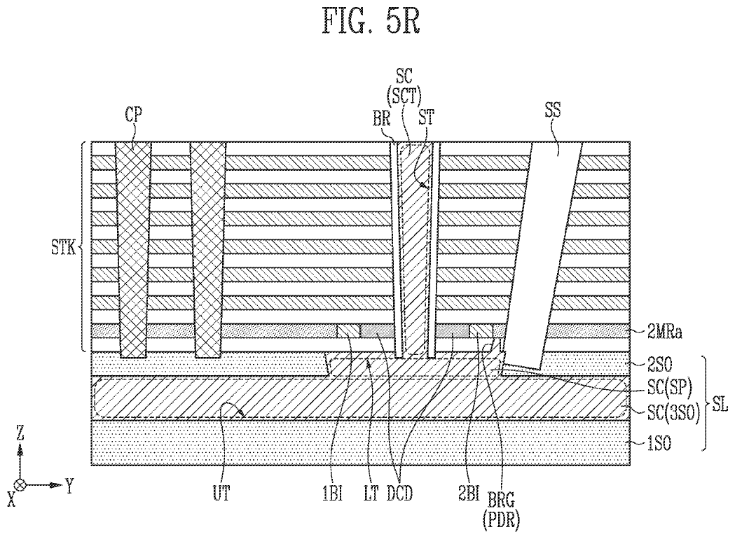

FIGS. 5A to 5R are views illustrating a manufacturing method of the memory device in accordance with the first embodiment of the present disclosure.

Referring to FIG. 5A, a first protective layer 1PT, a sacrificial layer SF, a second protective layer 2PT, and a second source layer 2SO may be stacked on a first source layer 1SO. The first and second source layers 1SO and 2SO may be formed of a conductive material such as poly-silicon, tungsten or nickel. The first and second protective layers 1PT and 2PT may be formed of a material having an etch selectivity different from an etch selectivity of the first and second source layers 1SO and 2SO. For example, the first and second protective layers 1PT and 2PT may be formed of an oxide layer.

Referring to FIG. 5B, a landing trench LT exposing a portion of the second protective layer 2PT may be formed in the second source layer 2SO. In order to form the landing trench LT, an anisotropic dry etching process may be performed. The etching process may be performed using a source gas having an etch selectivity with respect to the second source layer 2SO, which is higher than an etch selectivity with respect to the second protective layer 2PT. The upper width of the landing trench LT is defined as a first width 1W.

Referring to FIG. 5C, an etch stop layer ES may be formed in the landing trench LT. The etch stop layer ES may be used as a layer for stopping an etching process of forming a slit trench in the slit region. For example, the etch stop layer ES may be formed of tungsten.

Referring to FIG. 5D, a first material layer 1MRa and second material layers 2MRa may be stacked on the top of the etch stop layer ES and the second source layer 2SO. The first material layer 1MRa may be formed of an oxide layer, and the second material layers 2MRa may be formed of a nitride layer.

Referring to FIG. 5E, first and second isolation trenches 1DT and 2DT exposing portions of the first material layer 1MRa may be formed by etching portions of the second material layers 2MRa. The first isolation trench 1DT and the second isolation trench 2DT may be spaced apart from each other, and the width between an end of the first isolation trench 1DT and an end of the second isolation trench 2DT may become a second width 2W narrower than the first width 1W. For example, the width between an outer side surface of the first isolation trench 1DT and an outer side surface of the second isolation trench 2DT may be the second width 2W. Since the first and second isolation trenches 1DT and 2DT are spaced apart from each other, the width between an inner side surface of the first isolation trench 1DT and an inner side surface of the second isolation trench 2DT may be a third width 3W narrower than the second width 2W.

Referring to FIG. 5F, first and second blocking insulating layers 1BI and 2BI may be formed in the first and second isolation trenches 1DT and 2DT. For example, a blocking insulating layer may be formed on the entire structure to be filled in the first and second isolation trenches 1DT and 2DT. Subsequently, an etching or polishing process may be performed such that the second material layers 2MRa are exposed. Therefore, the blocking insulating layer remaining in the first isolation trench 1DT becomes the first blocking insulating layer 1BI, and the blocking insulating layer remaining in the second isolation trench 2DT becomes the second blocking insulating layer 2BI. Since the first and second blocking insulating layers 1BI and 2BI are formed in the first and second isolation trenches 1DT and 2DT, the width between outer side surfaces of the first and second blocking insulating layers 1BI and 2BI may be the second width 2W, and the width between inner side surfaces of the first and second blocking insulating layers 1BI and 2BI may be the third width 3W.

Referring to FIGS. 5F and 5G, the first and second blocking insulating layers 1BI and 2BI extend along the X direction, and therefore, the second material layers 2MRa may be isolated into first to third parts 1PN to 3PN by the first and second blocking insulating layers 1BI and 2BI. For example, the first and second parts 1PN and 2PN may be separated from each other by the first blocking insulating layer 1BI, and the second and third parts 2PN and 3PN may be separated from each other by the second blocking insulating layer 2BI.

Referring to FIG. 5H, first and second material layers 1MRb to 1MRh and 2MRb to 2MRg may be alternately stacked on the entire structure including the first and second blocking insulating layers 1BI and 2BI. The first material layers 1MRb to 1MRh may be formed of the same material as the first material layer 1MRa, and the second material layers 2MRb to 2MRg may be formed of the same material as the second material layers 2MRa. Accordingly, a pre-stack structure pSTK may be formed, which includes the first and second blocking insulating layers 1BI and 2BI, the first material layers 1MRa to 1MRh, and the second material layers 2MRa to 2MRg.

Referring to FIG. 5I, vertical holes VH penetrating the pre-stack structure pSTK may be formed in a cell region CELL of the pre-stack structure pSTK. For example, the vertical holes VH exposing the second source layer 2SO may be formed by etching portions of the pre-stack structure pSTK of the cell region CELL. The etch stop layer ES and the first and second blocking insulating layers 1BI and 2BI may be included in a peripheral region PER adjacent to the cell region CELL.

Referring to FIG. 5J, cell plugs CP may be formed in the vertical holes VH. The cell plugs CP may include memory cells. For example, each of the cell plugs may include a core pillar CR, a channel layer CH, a tunnel insulating layer TX, a charge trap layer CT, and a blocking layer BX, which constitute the memory cell. The core pillar CR may have a circular pillar shape, and be formed of an insulating material or a conductive material. The channel layer CH may have a cylindrical shape surrounding a side surface of the core pillar CR, and be formed of poly-silicon. The tunnel insulating layer TX may have a cylindrical shape surrounding a side surface of the channel layer CH, and be formed of an oxide layer. The charge trap layer CT may have a cylindrical shape surrounding a side surface of the tunnel insulating layer TX, and be formed of a nitride layer. The blocking layer BX may have a cylindrical shape surrounding a side surface of the charge trap layer CT, and be formed of an oxide layer.

Referring to FIG. 5K, an etching process for forming a support hole SH exposing the second source layer 2SO in the pre-stack structure pSTK of the peripheral region PER may be performed. The etching process may be performed as an anisotropic dry etching process to etch a portion of the pre-stack structure pSTK, which is adjacent to the second blocking insulating layer 2BI, in the vertical direction. When the anisotropic dry etching process is performed, the support hole SH is to be formed in the vertical direction (SHa), but an inclined support hole SH may be formed. The etch stop layer ES may be exposed through a lower portion of the support hole SH.

When the etch stop layer ES is exposed in the etching process for forming the support hole SH, ions IN of an etching gas used in the etching process may be introduced to the etch stop layer ES. Therefore, as the shape of the etch stop layer ES is partially deformed, a protrusion pattern PD may be formed. When the protrusion pattern PD is formed in the Z direction, the protrusion pattern PD may be in contact with the second material layers 2MRa or the second blocking insulating layer 2BI. When a conductive line corresponding to a source select line instead of the second material layers 2MRa or the second blocking insulating layer 2BI is located in a region in which the protrusion pattern PD is in contact with the second material layers 2MRa or the second blocking insulating layer 2BI, a source line SL and the conductive line are electrically connected to each other, and therefore, an error occurs in an operation of the memory device. However, in this embodiment, although the protrusion pattern PD is formed to be in contact with a line located on the top thereof, any error due to a bridge does not occur in the operation of the memory device because the line in contact with the protrusion pattern PD is an insulative line which is not used in a memory block.

Referring to FIG. 5L, a support structure SS may be formed in the support hole SH. The support structure SS may be formed of an insulating material. For example, an insulating material corresponding to the support structure SS may be formed on the entire structure including the support hole SH to be filled in the support hole SH. Subsequently, a planarization process may be performed until the pre-stack structure pSTK is exposed, so that the support structure SS remain in the support hole SH.

Referring to FIG. 5M, a slit trench ST may be formed, which penetrates the pre-stack structure pSTK between the first and second blocking insulating layers 1BI and 2BI. Regions of memory blocks may be separated from each other by the slit trench ST.

The slit trench ST may be formed through an anisotropic etching process. The etching process for forming the slit trench ST may be performed until the etch stop layer ES is exposed. The width between the slit trench ST and the first blocking insulating layer 1BI may be a fourth width 4W, and the width between the slit trench ST and the second blocking insulating layer 2BI may be a fifth width 5W. The fourth width 4W and the fifth width 5W may be different from each other or be equal to each other. When the slit trench ST is formed in the pre-stack structure pSTK, side surfaces of the first and second material layers 1MRa to 1MRh and 2MRa to 2MRg and a portion of the top surface of the etch stop layer ES may be exposed through the slit trench ST.

Referring to FIG. 5N, an etching process for removing the second material layers (2MRa to 2MRg shown in FIG. 5L) exposed through the slit trench ST may be performed. A wet etching process using an etchant having an etch selectivity with respect to the second material layers 2MRa to 2MRg, which is higher than an etch selectivity with respect to the first material layers 1MRa to 1MRh, may be performed as the etching process. Portions of the second material layers 2MRa, which are not exposed by the first and second blocking insulating layers 1BI and 2BI, are not removed but may remain. For example, since each of the second material layers 2MRb to 2MRg formed in the same layer extend to each other, each of the second material layers 2MRb to 2MRg are simultaneously removed through the slit trench ST. However, only a portion of the second material layer 2MRa located at a lowermost portion may be exposed through the slit trench ST. When the exposed portion is removed through the slit trench ST, the other second material layers 2MRa are not removed by the second blocking insulating layers 1BI and 2BI but may remain.

Referring to FIG. 5O, gate conductive layers CDa to CDf may be formed in regions in which the second material layers 2MRa to 2MRg are removed. The gate conductive layers CDa to CDf may be formed of a metal material such as tungsten (W), molybdenum (Mo), cobalt (Co) or nickel (Ni), or a semiconductor material such as silicon (Si) or poly-silicon (Poly-Si), but the present disclosure is not limited thereto. A gate conductive layer is filled even in a layer in which the first and second blocking insulating layers 1BI and 2BI. Since the gate conductive layer formed in the layer is not used as a gate, the gate conductive layer becomes a dummy conductive layer DCD.

Each of the gate conductive layers CDa to CDf may be used as a source select line SSL, a word line, or a drain select line according to a position thereof. For example, among the gate conductive layers CDa to CDf, a gate conductive layer CDa located at a lower portion may be used as the source select line SSL, a gate conductive layer CDf located at a upper portion may be used as the drain select line DSL, and gate conductive layers CDb to CDe located between the source select line SSL and the drain select line DSL may be used as word lines WL. FIG. 5O is a view schematically illustrating a structure of the memory block BLK, and therefore, the number of each of the source select line SSL, the word line WL, and the drain select line DSL is not limited to that shown in FIG. 5O.

As the gate conductive layers CDa to CDf are formed, a stack structure STK may be formed, which includes the gate conductive layers CDa to CDf, the dummy conductive layer DCD, the first material layers 1MRa to 1MRh, the second material layers 2MRa, and the first and second blocking insulating layers 1BI and 2BI.

After the gate conductive layers CDa to CDf and the dummy conductive layer DCD are formed, an etching process for removing conductive layers extending in the vertical direction from a side surface of the slit trench ST may be performed such that the gate conductive layers CDa to CDf or the dummy conductive layer DCD, which are located in different layers, are spaced apart from each other.

Referring to FIG. 5P, a barrier layer BR may be formed on the side surface of the slit trench ST. The barrier layer BR may be formed of an insulating material an etch selectivity different from an etch selectivity of the etch stop layer ES. Since the barrier layer BR is formed on the side surface of the slit trench ST, the etch stop layer ES may be exposed through a lower portion of the slit trench ST.

Referring to FIGS. 5P and 5Q, the etch stop layer ES exposed through the slit trench ST may be removed. As the etch stop layer ES is removed, the second protective layer 2PT, the sacrificial layer SF, and the first protective layer 1PT, which are sequentially exposed, may also be removed through the slit trench ST. An etching process for removing the etch stop layer ES, the second protective layer 2PT, the sacrificial layer SF, and the first protective layer 1PT may be performed as a wet etching process. A region in which the second protective layer 2PT, the sacrificial layer SF, and the first protective layer 1PT are removed may become a lower trench UT, and a region in which the etch stop layer ES is removed may become a landing trench LT. When the etch stop layer ES is removed, the protrusion pattern PD is also removed. Therefore, a protrusion region PDR exposing the second material layers 2MRa or the second blocking insulating layer 2BI may be formed. That is, the protrusion region PDR may be connected to the landing trench LT. Therefore, the lower trench UT, the landing trench LT, the protrusion region PDR, and the slit trench ST may be connected to each other.

Referring to FIG. 5R, a source conductive layer SC may be formed through the slit trench ST. Therefore, the source conductive layer SC filled in the lower trench UT may become a third source layer 3SO, the source conductive layer SC filled in the landing trench LT and the protrusion region PDR may become a source pad SP, and the source conductive layer SC filled in the slit trench ST may become a source contact SCT. Accordingly, the source line SL may be formed which includes the first to third source layers 1SO to 3SO and the source pad SP.

The third source layer 3SO, the source pad SP, and the source contact SCT may be formed of a conductive material such as poly-silicon, tungsten or nickel. The third source layer 3SO, the source pad SP, and the source contact SCT may be formed of the same conductive material. The source contact SCT may be formed of a conductive material different from a conductive material of the third source layer 3SO or the source pad SP.

Since the source conductive layer SC is also filled in the protrusion region PDR, the source conductive layer SC filled in the protrusion region PDR may become a bridge BRG connecting an upper structure and the source line SL to each other. However, in this embodiment, since the bridge BRG protruding from the source line SL is in contact with the second material layers 2MRa or the second blocking insulating layer 2BI, which is made of an insulating material, a voltage applied to the source line SL is not transferred to other lines except the source line SL. Thus, in an embodiment, a defect due to the bridge BRG occurring in the source line SL can be reduced.

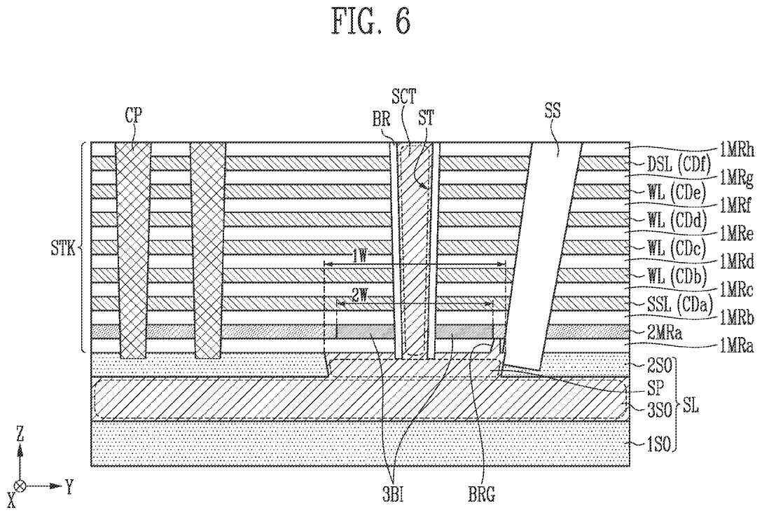

FIG. 6 is a sectional view illustrating a memory block in accordance with a second embodiment of the present disclosure.

Referring to FIG. 6, in the second embodiment, third blocking insulating layers 3BI in contact with the barrier layer BR may be formed instead of the first and second insulating layers (1BI and 2BI, which are shown in FIG. 3) described in the first embodiment. The third blocking insulating layers 3BI are isolated from each other by a source trench ST. However, the third blocking insulating layers 3BI may be formed as one structure in a manufacturing process. For example, in FIG. 5E of the first embodiment, the second material layers 2MRa are located between the first and second isolation trenches 1DT and 2DT. However, in the second embodiment, one isolation trench may be formed in a region in which the second material layers 2MRa between the first and second isolation trenches 1DT and 2DT of the first embodiment and the first and second isolation trenches 1DT and 2DT are formed. After one isolation trench is formed, the isolation trench is isolated by the slit trench ST, and therefore, the third blocking insulating layers 3BI isolated from each other by the source trench ST may be formed as shown in FIG. 6. The width between both ends of the third blocking insulating layers 3BI may be the second width 2W.

In the second embodiment, the second material layers 2MRa remain thanks to the third blocking insulating layers 3BI. Thus, although the bridge BRG occurs from the source line SL, the bridge BRG and the source select line SSL can be spaced apart from each other.

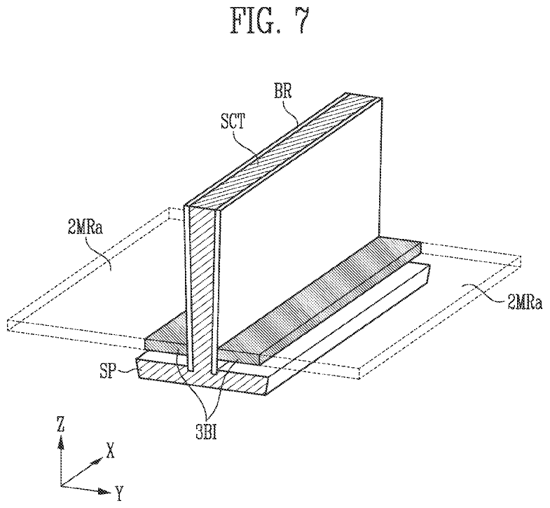

FIG. 7 is a perspective view illustrating the memory block in accordance with the second embodiment of the present disclosure.

Referring to FIG. 7, the third blocking insulating layers 3BI and the second material layers 2MRa may be located in the same layer. The source pad SP may be located under the third blocking insulating layers 3BI and the second material layer 2MRa, and the source contact SCT and the barrier layer BR may in contact with the source pad SP while penetrating between the third blocking insulating layers 3BI. Therefore, the third blocking insulating layers 3BI may be in contact with the barrier layer BR and the second material layers 2MRa.

The third blocking insulating layers 3BI may extend along the X direction in which the source contact SCT extends, to isolate the second material layers 2MRa from each other.

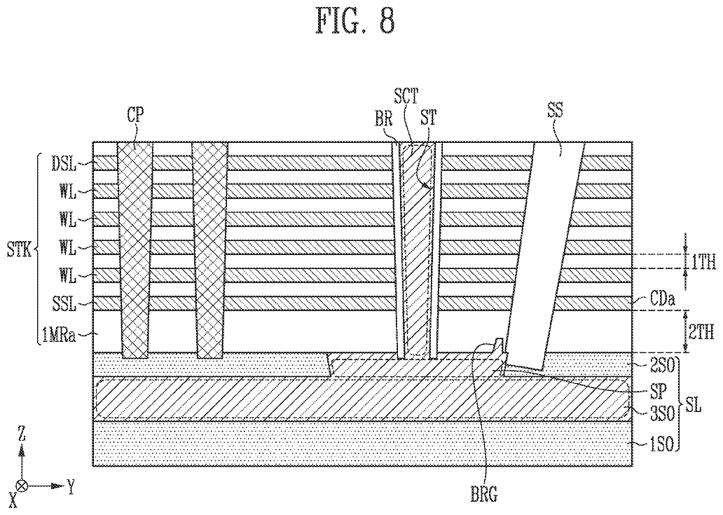

FIG. 8 is a sectional view illustrating a memory block in accordance with a third embodiment of the present disclosure.

Referring to FIG. 8, in the third embodiment, the blocking insulating layers 1BI and 2BI of the first embodiment or the third blocking insulating layer 3BI of the second embodiment are not formed, but the thickness of the first material layer 1MRa located at a lowermost end of the stack structure STK may be increased. That is, the first material layer 1MRa made of an insulating material may be located between the source select line SSL and the source line SL. When assuming that the thickness between the source select line SSL, the word lines WL, and the drain select line DSL, which are included in the stack structure STK, is a first thickness 1TH, the thickness of the first material layer 1MRa located at the lowermost end may be a second thickness 2TH thicker than the first thickness 1TH. Thus, although the bridge BRG protruding upwardly from the source line SL occurs, the bridge BRG is not in contact with the source select line SSL. Thus, in an embodiment, occurrence of a defect between the source line SL and the source select line SSL can be reduced.

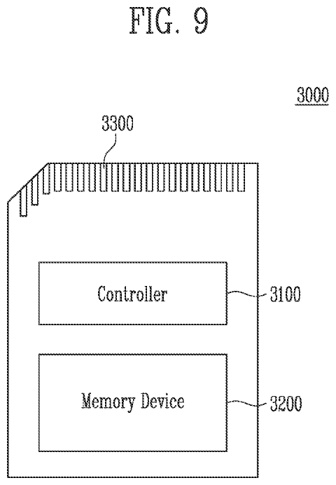

FIG. 9 is a diagram illustrating a memory card system to which the memory device of the present disclosure is applied.

Referring to FIG. 9, the memory card system 3000 includes a controller 3100, a memory device 3200, and a connector 3300.

The controller 3100 may be connected to the memory device 3200. The controller 3100 may access the memory device 3200. For example, the controller 3100 may control a program, read or ease operation, or control a background operation of the memory device 3200. The controller 3100 may provide an interface between the memory device 3200 and a host. The controller 3100 may drive firmware for controlling the memory device 3200. For example, the controller 3100 may include components such as a Random Access Memory (RAM), a processing unit, a host interface, a memory interface, and the error corrector.

The controller 3100 may communicate with an external device through the connector 3300. The controller 3100 may communicate with the external device (e.g., the host) according to a specific communication protocol. Exemplarily, the controller 3100 may communicate with the external device through at least one of various communication protocols such as a Universal Serial Bus (USB), a Multi-Media Card (MMC), an embedded MMC (eMMC), a Peripheral Component Interconnection (PCI), a PCI express (PCIe), an Advanced Technology Attachment (ATA), a Serial-ATA (SATA), a Parallel-ATA (PATA), a Small Computer System Interface (SCSI), an Enhanced Small Disk Interface (ESDI), an Integrated Drive Electronics (IDE), firewire, a Universal Flash Storage (UFS), Wi-Fi, Bluetooth, and NVMe. Exemplarily, the connector 3300 may be defined by at least one of the above-described various communication protocols.

The memory device 3200 may include memory cells, and be configured identically to the memory device 100 shown in FIG. 1.

The controller 3100 and the memory device 3200 may be integrated into a single semiconductor device, to constitute a memory card. For example, the controller 3100 and the memory device 3200 may constitute a memory card such as a personal computer (PC) card (Personal Computer Memory Card International Association (PCMCIA)), a Compact Flash (CF) card, a Smart Media Card (SM and SMC), a memory stick, a Multi-Media Card (MMC, RS-MMC, MMCmicro and eMMC), an SD card (SD, miniSD, microSD and SDHC), and a Universal Flash Storage (UFS).

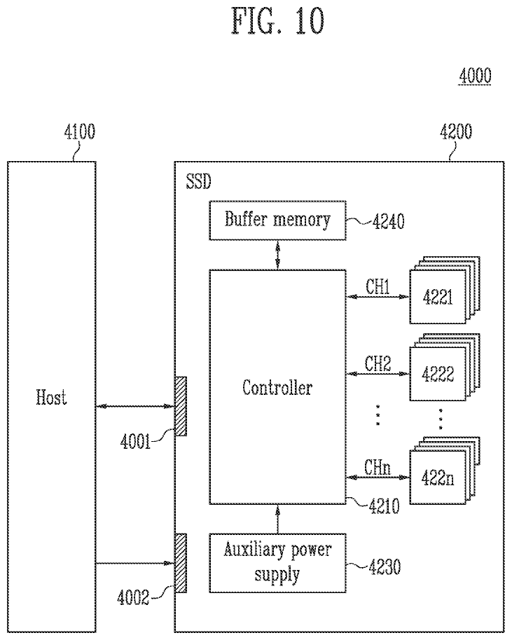

FIG. 10 is a diagram illustrating a Solid State Drive (SSD) system to which the memory device of the present disclosure is applied.

Referring to FIG. 10, the SSD system 4000 includes a host 4100 and an SSD 4200. The SSD 4200 exchanges a signal with the host 4100 through a signal connector 4001, and receives power through a power connector 4002. The SSD 4200 includes a controller 4210, a plurality of memory devices 4221 to 422n, an auxiliary power supply 4230, and a buffer memory 4240.

The controller 4210 may control the plurality of memory devices 4221 to 422n in response to a signal received from the host 4100. Exemplarily, the signal may be a signal based on an interface between the host 4100 and the SSD 4200. For example, the signal may be a signal defined by at least one of interfaces such as a Universal Serial Bus (USB), a Multi-Media Card (MMC), an embedded MMC (eMMC), a Peripheral Component Interconnection (PCI), a PCI express (PCIe), an Advanced Technology Attachment (ATA), a Serial-ATA (SATA), a Parallel-ATA (PATA), a Small Computer System Interface (SCSI), an Enhanced Small Disk Interface (ESDI), an Integrated Drive Electronics (IDE), a firewire, a Universal Flash Storage (UFS), a WI-FI, a Bluetooth, and an NVMe.

The plurality of memory devices 4221 to 422n may include a plurality of memory cells configured to store data. Each of the plurality of memory devices 4221 to 422n may be configured identically to the memory device 100 shown in FIG. 1. The plurality of memory devices 4221 to 422n may communicate with the controller 4210 through channels CH1 to CHn.

The auxiliary power supply 4230 may be connected to the host 4100 through the power connector 4002. The auxiliary power supply 4230 may receive power PWR input from the host 4100 and charge the power PWR. When the supply of power from the host 4100 is not smooth, the auxiliary power supply 4230 may provide power of the SSD 4200. For example, the auxiliary power supply 4230 may be located in the SSD 4200, or be located at the outside of the SSD 4200. For example, the auxiliary power supply 4230 may be located on a main board, and provide auxiliary power to the SSD 4200.

The buffer memory 4240 may operate as a buffer memory of the SSD 4200. For example, the buffer memory 4240 may store data received from the host 4100 or data received from the plurality of memory devices 4221 to 422n, or store meta data (e.g., a mapping table) of the memory devices 4221 to 422n. The buffer memory 4240 may include volatile memories such as a DRAM, an SDRAM, a DDR SDRAM, an LPDDR SDRAM, and a GRAM or nonvolatile memories such as a FRAM, a ReRAM, an STT-MRAM, and a PRAM.

In accordance with an embodiment of the present disclosure, a defect which may occur in a manufacturing process of the memory device is reduced, so that the yield of the manufacturing process of the memory device can be improved.

While the present disclosure has been shown and described with reference to certain embodiments thereof, it will be understood by those skilled in the art that various changes in form and details may be made therein without departing from the spirit and scope of the present disclosure as defined by the appended claims and their equivalents. Therefore, the scope of the present disclosure should not be limited to the above-described embodiments but should be determined by not only the appended claims but also the equivalents thereof.

In the above-described embodiments, all steps may be selectively performed or part of the steps and may be omitted. In each embodiment, the steps are not necessarily performed in accordance with the described order and may be rearranged. The embodiments disclosed in this specification and drawings are only examples to facilitate an understanding of the present disclosure, and the present disclosure is not limited thereto. That is, it should be apparent to those skilled in the art that various modifications can be made on the basis of the technological scope of the present disclosure.

Meanwhile, the embodiments of the present disclosure have been described in the drawings and specification. Although specific terminologies are used here, those are only to explain the embodiments of the present disclosure. Therefore, the present disclosure is not restricted to the above-described embodiments and many variations are possible within the spirit and scope of the present disclosure. It should be apparent to those skilled in the art that various modifications can be made on the basis of the technological scope of the present disclosure in addition to the embodiments disclosed herein.

What is claimed is:

1. A memory device comprising:
a source line;
a dummy stack structure located on the source line;
a main stack structure located on the dummy stack structure; and
a source contact in contact with the source line while penetrating the main stack structure and the dummy stack structure,
wherein the dummy stack structure includes:
a first material layer located on the source line; and
second material layers, blocking insulating layers, and dummy conductive layers, located on the first material layer, and
wherein the main stack structure includes insulating layers and gate conductive layers, which are alternately stacked on the dummy stack structure.

2. The memory device of claim 1, wherein the source line includes first, second, and third source layers and a source pad.

3. The memory device of claim 2, wherein the third source layer is located on the first source layer, and
wherein the second source layer and the source pad are located on the third source layer.

4. The memory device of claim 3, wherein the source pad is included in the second source layer, and
wherein top surfaces of the source pad and the second source layer are horizontal.

5. The memory device of claim 2, wherein the source contact is in contact with the source pad.

6. The memory device of claim 1, wherein the source contact penetrates the dummy stack structure between the dummy conductive layers to space apart the dummy conductive layers from each other.

7. The memory device of claim 1, wherein the first material layer, the blocking insulating layers, and the insulating layers comprises an oxide layer.

8. The memory device of claim 1, wherein the second material layers comprises a nitride layer.

9. The memory device of claim 1, wherein the dummy conductive layers and the gate conductive layers comprise of at least one material among tungsten, molybdenum, cobalt, nickel, silicon, and poly-silicon.

10. The memory device of claim 1, further comprising a support structure spaced apart from the source contact, the support structure being in contact with the source line while penetrating the main stack structure and the dummy stack structure.

11. The memory device of claim 10, wherein the support structure penetrates at least one second material layer among the second material layers of the dummy stack structure and the first material layer.

12. The memory device of claim 10, wherein the support structure comprises an oxide layer.

13. A memory device comprising:
a source pad included in a source line;
blocking insulating layers located on the source pad;
material layers located at both ends of the blocking insulating layers;
a source select line, a word line, and a drain select line, located on the blocking insulating layers and the material layers; and
a source contact in contact with the source pad while penetrating the drain select line, the word line, and the source select line,
wherein the source contact penetrates the blocking insulating layers to space apart the blocking insulating layers from each other.

14. The memory device of claim 13, wherein the source pad comprises of at least one material among poly-silicon, tungsten, and nickel.

15. The memory device of claim 13, wherein the source pad comprises a first width, and
wherein a width between both the ends of the blocking insulating layers is a second width, the second width is narrow than the first width.

16. The memory device of claim 13, wherein the blocking insulating layers comprise of an oxide layer.

17. The memory device of claim 13, wherein the material layers comprise of a nitride layer.

18. A method of manufacturing a memory device, the method comprising:
stacking a first material layer and a second material layer on a source layer including an etch stop layer;
forming first and second isolation trenches spaced apart from each other in the second material layer on the etch stop layer;
forming first and second blocking insulating layers in the first and second isolation trenches;
alternately stacking third material layers and fourth material layers on the first and second blocking insulating layers and the second material layer, thereby forming a pre-stack structure including the first to fourth material layers and the first and second blocking insulating layers;
forming a support structure in contact with the source layer while penetrating the pre-stack structure;
forming a slit trench penetrating the pre-stack structure between the first and second blocking insulating layers;
removing the second and fourth material layers exposed through the slit trench;
filling a first conductive layer in regions in which the second and fourth material layers are removed;
removing the etch stop layer exposed through the slit trench; and
filling a second conductive layer for a source pad in a region in which the etch stop layer is removed.

19. The method of claim 18, wherein the etch stop layer comprises a material having an etch selectivity different from an etch selectivity of the source layer.

20. The method of claim 18, wherein the etch stop layer comprises tungsten.

21. The method of claim 18, wherein the first and third material layers comprise of an oxide layer, and
the second and fourth material layers comprise of a nitride layer.

22. The method of claim 18, wherein the first and second blocking insulating layers comprise of an oxide layer.

23. The method of claim 18, wherein the forming of the support structure includes:
forming a support hole exposing the source layer while penetrating the pre-stack structure; and
forming the support structure by filling an insulating material in the support hole.

24. The method of claim 23, wherein an anisotropic dry etching process is performed to form the support hole.

25. The method of claim 18, wherein, in a layer in which the first and second blocking insulating layers are formed,
the first conductive layer is formed between the first and second blocking insulating layers, and
the second material layer remains at the outside of the first and second blocking insulating layers.
